(19) United States
(12) Patent Application Publication
(10) Pub. No.: US 2014/0298827 A1
(43) Pub. Date: Oct. 9, 2014

(54) TERMINAL APPARATUS OF SUPERCONDUCTING DEVICE

(71) Applicant: LS Cable & System Ltd., Anyang-si (KR)

(72) Inventors: Heo-Gyung SUNG, Gumi-si (KR); Hyun- Man JANG, Hwaseong-si (KR); Chang-Youl CHOI, Ansan-si (KR)

(73) Assignee: LS Cable & System Ltd., Anyang-si (KR)

(21) Appl. No.: 14/094,870

(22) Filed: Dec. 3, 2013

(30) Foreign Application Priority Data
Jan. 23, 2013 (KR) 10-2013-0007477

(51) Int. Cl. H01L 39/04

(52) U.S. Cl. CPC H01L 39/04
USPC 62/49.2; 220/560.1; 165/63

(57) ABSTRACT

The present invention relates to a terminal apparatus of a superconducting device that is capable of minimizing the use of dividing members for dividing a liquid refrigerant, a vapor refrigerant or a room temperature insulating material, thereby preventing sealing members like O-rings mounted on the respective dividing members from being damaged.

### CROSS REFERENCE TO RELATED APPLICATION

This application claims the benefit of the Patent Korean Application No. 10-2013-0007477, filed on Jan. 23, 2013, which is hereby incorporated by reference as if fully set forth herein.

### BACKGROUND OF THE INVENTION

1. Field of the Invention

The present invention relates to a terminal apparatus of a superconducting device, and more particularly, to a terminal apparatus of a superconducting device that is capable of minimizing the use of dividing members for dividing a liquid refrigerant, a vapor refrigerant or a room temperature insulating material, thereby preventing sealing members like O-rings mounted on the respective dividing members from being damaged.

2. Background of the Related Art

A superconductor has zero electric resistance at a given temperature and thus provides a high current transfer capacity even at a low voltage.

A superconducting device with such superconductor forms and maintains a cryogenic temperature environment by cooling a refrigerant like nitrogen and/or forms a vacuum layer through insulation. An example of the superconducting device is a superconducting cable.

The current transmitted through the superconducting device is connected to a conductor wire being at a room temperature environment through a terminal apparatus of the superconducting device.

So as to avoid the problems caused when the environment where the superconductor is exposed is suddenly changed from a cryogenic temperature environment to a room temperature environment, the terminal apparatus of the superconducting device connects the superconductor to the conductor wire and draws the connected conductor wire to the room temperature environment, while ensuring sufficient temperature gradient between the cryogenic temperature environment and the room temperature environment.

Accordingly, the terminal apparatus is divided into a room temperature part, a temperature gradient part and a cryogenic temperature part in the direction from the upper end to the lower end thereof in accordance with temperatures. The cryogenic temperature part contains a cryogenic temperature liquid refrigerant therein, the temperature gradient part contains a vapor refrigerant located on top of the liquid refrigerant therein in such a manner as to have the temperature gradient between a cryogenic temperature and a room temperature, and the room temperature part is at the room temperature environment.

As a result, as the conductor wire connected to the superconductor is passed through the cryogenic temperature part, the temperature gradient part and the room temperature part, it is slowly exposed to the room temperature environment from the cryogenic temperature environment.

Like this, the terminal apparatus of the superconducting device reduces the occurrence of the insulation breakdown caused by the drastic temperature change, while supplying the current supplied from the superconductor to the conductor wire being at a room temperature.

However, conventional terminal apparatuses of a superconducting device have the following problems.

As one of prior art documents, there is disclosed Korean Patent Application No. 10-2011-0005534 (hereinafter, referred to as “first prior art document”) wherein a terminal apparatus of a superconducting device divides a cryogenic temperature part and a temperature gradient part by means of a sealing plate, thereby physically dividing a cryogenic temperature liquid refrigerant and a vapor refrigerant having temperature gradient. In this case, however, it is not easy to ensure the airtightness or durability of the sealing plate exposed to the cryogenic temperature liquid refrigerant and a sealing member (O-ring and the like) mounted on the sealing plate, and further, it is not desirable that the cryogenic temperature liquid refrigerant and the vapor refrigerant are shielded from each other by means of an artificial structure.

Moreover, a second pipe body and a third pipe body containing the liquid refrigerant and the vapor refrigerant are formed unitarily with each other, and in this case, no problem occurs on the airtightness or durability of the sealing member (O-ring and the like) mounted on the sealing plate. However, there is no method for adjusting the liquid surface of the liquid refrigerant contained below the sealing plate. Even though the liquid refrigerant is contained under the sealing plate, that is, it is not desirable that the liquid refrigerant is directly contacted with the sealing plate.

According to the first prior art document, however, there is no method for preventing the liquid surface of the liquid refrigerant from being increased and directly contacted with the sealing plate.

Further, there is disclosed Korean Patent Application No. 10-2011-0085717 (hereinafter, referred to as “second prior art document”) wherein a terminal apparatus of a superconducting device improves the connection and insulation structures of a conductor wire in a temperature gradient part in such a manner as to detachably mount the temperature gradient part, so as to improve the assembly, structural strength, and insulation strength of the temperature gradient part. In the same manner as the first prior art document, however, the second prior art document has the structure where a spacer member dividing a cryogenic temperature part and a temperature gradient part is exposed directly to a cryogenic temperature liquid refrigerant, so that it is not easy to ensure the airtightness or durability of a sealing member (O-ring and the like) mounted on the spacer member and further there is no liquid surface location adjusting method for preventing the liquid surface of the liquid refrigerant from being directly contacted with the spacer member.

Furthermore, there is disclosed Japanese Patent Application No. 2011-160641 (hereinafter, referred to as “third prior art document”) wherein a terminal apparatus of a superconducting device contains a liquid refrigerant layer on the lower part of an inside pressure container and refrigerant gas contained on the upper part thereof. According to the third prior art document, no shielding part like a sealing plate or spacer member is located between the cryogenic temperature part containing the liquid refrigerant therein and the temperature gradient part containing vapor refrigerant, so that there is no problem caused when the sealing plate or the spacer member and the sealing member like O-ring mounted on the sealing plate or the spacer member are exposed directly to the cryogenic temperature liquid refrigerant. According to the third prior art document, a high voltage drawing part as the room temperature part is divided from the refrigerant gas layer contained in the temperature gradient part by means of a flange, but there is no method for adjusting the liquid surface of the liquid refrigerant between the cryogenic temperature part and the temperature gradient part.

If the liquid surface of the liquid refrigerant is abnormally increased, accordingly, the flange dividing the room temperature part and the temperature gradient part may be exposed to the cryogenic temperature liquid refrigerant, so that it is not easy to ensure the airtightness or durability of the sealing member.

According to the third prior art document, further, in the state where the conductor wire and bushing provided on the cryogenic temperature part and the temperature gradient part are passed through the flange and extended to the room temperature part, there is no structure for detachably mounting the room temperature part on the temperature gradient part, so that it is not easy to connect with other external devices.

Moreover, in the state where no dividing members such as partition, flange or spacer are provided between the cryogenic temperature part where the liquid refrigerant is contained and the temperature gradient part in which the vapor refrigerant is contained, the third prior art document just ensures the airtightness or durability of the sealing member.

While removing any dividing members such as partition, flange or spacer are provided between the cryogenic temperature part where the liquid refrigerant is contained and the temperature gradient part in which the vapor refrigerant is contained, accordingly, a method for artificially adjusting the liquid surface of the liquid refrigerant has been disclosed in Japanese Patent Application No. 2011-40705 (hereinafter, referred to as “fourth prior art document”).

According to the fourth prior art document, that is, the terminal apparatus of a superconducting device has a liquid surface adjusting means for adjusting the liquid surface of the liquid refrigerant in a refrigerant container, and if the liquid surface is increased, it forcedly supplies a vapor refrigerant to the temperature gradient part through the liquid surface adjusting means, thereby preventing the liquid surface of the liquid refrigerant from approaching the cryogenic temperature part and the temperature gradient part. If a separate gas supply pipe is formed on the temperature gradient part, however, the reliability of the airtightness of the temperature gradient part may be deteriorated.

In the same manner as above, according to the fourth prior art document, in the state where the conductor wire and bushing provided on the cryogenic temperature part and the temperature gradient part are extended to the room temperature part, there is no structure for detachably mounting the room temperature part on the temperature gradient part, so that it is not easy to connect with other external devices.

On the other hand, there is disclosed Korean Patent Application No. 10-2007-0102651 (hereinafter, referred to as “fifth prior art document”) wherein a terminal apparatus of a superconducting device reduces the gap between the inner surface of the refrigerant container and the outer peripheral surface of a bushing to control the liquid surface to be naturally located at a temperature gradient part, but since it is applied just to a specific experimental condition, it is not applicable to general conditions, thereby failing to ensure the airtightness or durability of a flange. In the same manner as above, there is no mention of the liquid surface location adjusting means for decreasing the location of liquid surface of the liquid refrigerant, thereby causing the above-mentioned problems.

In the same manner as above, according to the fifth prior art document, in the state where the conductor wire and bushing provided on the cryogenic temperature part and the temperature gradient part are extended to the room temperature part, there is no mention of a structure for detachably mounting the room temperature part on the temperature gradient part, so that it is not easy to connect with other external devices.

### SUMMARY OF THE INVENTION

In accordance with an aspect of the present invention, the above and other objects can be accomplished by the provision of a terminal apparatus of a superconducting device comprising a refrigerant container having a cryogenic temperature part formed in the lower part thereof, the cryogenic temperature part containing a liquid refrigerant therein, and a temperature gradient part formed above the cryogenic temperature part, the temperature gradient part containing a vapor refrigerant having temperature gradient therein, a sealing member for sealing the top end of the refrigerant container, a room temperature part housing mounted on top of the sealing member in such a manner as to form a room temperature part in which insulating oil or insulating gas contained, a vacuum container for surrounding the refrigerant container except a part of the upper part thereof and a conductor wire connected to a superconductor of the superconducting device into the liquid refrigerant contained in the refrigerant container in such a manner as to be passed through the sealing member and extended to the room temperature part housing.

The vacuum container may surround the refrigerant container in such a manner as to allow the region beneath the top end of the refrigerant container to be exposed to the outside.

The region beneath the top end of the refrigerant container exposed to the outside of the vacuum container may have a height at which the liquid surface of the liquid refrigerant contained in the refrigerant container is located at a range between the lower end part of a bushing surrounding the conductor wire and the sealing member.

The terminal apparatus of a superconducting device may comprise at least one or more liquid level controlling units mounted on the temperature gradient part or the cryogenic temperature part to vaporize the liquid refrigerant on the liquid surface in such a manner as to control the liquid surface of the liquid refrigerant to be located at a predetermined range.

The liquid level controlling units may comprise electric heaters mounted on the outer peripheral surface of the refrigerant container forming the temperature gradient part.

The liquid level controlling units may be mounted spaced apart from each other on the outer peripheral surface of the refrigerant container forming the temperature gradient part.

The terminal apparatus of a superconducting device may further comprise a controller adapted to control the liquid level controlling units in such a manner as to control the liquid surface of the liquid refrigerant contained in the refrigerant container to be located at the predetermined range.

The lower end of the predetermined range may be located at the height of the foil electrode disposed at the uppermost position among a plurality of foil electrodes mounted on the bushing located on the lower part of the conductor wire.

The upper end of the predetermined range may be located at the height of the lower end of the liquid level controlling unit mounted on the temperature gradient part.

The liquid level controlling units may be mounted spaced apart from each other on the outer peripheral surface of the refrigerant container forming the temperature gradient part, and the upper end of the predetermined range is located at the height of the lower end of the liquid level controlling unit disposed at the lowermost position among the liquid level controlling units mounted on the temperature gradient part.

And in accordance with an aspect of the present invention, the above and other objects can be accomplished by the provision of a terminal apparatus of a superconducting device, comprising a refrigerant container having a liquid refrigerant contained in the lower part thereof and a vapor refrigerant contained on top of the liquid surface of the liquid refrigerant, a first conductor wire connected to a superconductor of the superconducting device in such a manner as to have the lower part submerged into the liquid refrigerant contained in the refrigerant container and the upper part extended to the upper part of the refrigerant container in which the vapor refrigerant is contained, a sealing member for sealing the top end of the refrigerant container, a second conductor wire detachably connected to the first conductor wire by means of the sealing member in such a manner as to be extended upwardly, a room temperature part housing detachably mounted on the sealing member to surround the second conductor wire and containing insulating oil or insulating gas therein and a vacuum container for surrounding the space where the liquid refrigerant is contained and a part of the space where the vapor refrigerant is contained in the refrigerant container to be vacuum-insulated.

The sealing member may comprise a conductive connector disposed at the center part thereof to couple the first conductor wire and the second conductor wire to each other.

The terminal apparatus of a superconducting device may further comprise at least one or more electric heaters mounted on the outer peripheral surface of the upper part of the refrigerant container in such a manner as to selectively generate heat therefrom to adjust the location of the liquid surface of the liquid refrigerant contained in the refrigerant container.

The electric heaters may be mounted spaced apart from each other on the outer peripheral surface of the refrigerant container, some of the electric heaters being mounted inside the vacuum container and the others being mounted on the outer peripheral surface of the refrigerant container exposed to the outside of the vacuum container.

The terminal apparatus of a superconducting device may further comprise a controller adapted to control the electric heaters to control the operating start point, operating time, and the heating value per unit time of at least one electric heater among the electric heaters to be different from those of the other electric heaters or to control the operating start points, operating time, and the heating values per unit time of the electric heaters to be same as each other.

The controller may control the electric heater mounted on the outer peripheral surface of the refrigerant container exposed to the outside of the vacuum container to control the operating time thereof to be longer than that of the other electric heaters.

The controller may control the electric heater mounted on the outer peripheral surface of the refrigerant container exposed to the outside of the vacuum container to control the operating start point thereof to be rapider than those of the other electric heaters.

The controller may control the electric heater mounted on the outer peripheral surface of the refrigerant container exposed to the outside of the vacuum container to allow the heating value per unit time thereof to be larger than those of the other electric heaters.

And in accordance with an aspect of the present invention, the above and other objects can be accomplished by the provision of a terminal apparatus of a superconducting device, comprising a cryogenic temperature part adapted to contain a liquid refrigerant therein, in which a lower part of a conductor wire is submerged, the conductor wire being connected to a superconductor and having a bushing fitted on the outer periphery thereof, a temperature gradient part adapted to communicate with the cryogenic temperature part, containing a vapor refrigerant to be contained to have temperature gradient and having the conductor wire extended upwardly from the cryogenic temperature part and a room temperature part divided from the temperature gradient part and having the conductor wire extended from the cryogenic temperature part and the temperature gradient part in such a manner as to be drawn therefrom, wherein the cryogenic temperature part and a part of the temperature gradient part are vacuum-insulated, and a part of the region beneath the top end of the temperature gradient part is exposed to the outside.

The terminal apparatus of a superconducting device may further comprise at least one or more electric heaters mounted on the temperature gradient part or the cryogenic temperature part to vaporize the liquid refrigerant on the liquid surface in such a manner as to control the liquid surface of the liquid refrigerant to be located at a predetermined range.

At least one electric heater of the electric heaters may be mounted on the outer peripheral surface of the refrigerant container forming the temperature gradient part exposed to the outside.

The room temperature part may be detachably mounted on the temperature gradient part.

The room temperature part and the temperature gradient part may be divided from each other by means of the sealing member and have respective conductor wires detachably fastened to each other by means of the sealing member.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a sectional view showing a terminal apparatus of a superconducting device according to a first embodiment of the present invention;

FIG. 2 is a sectional view showing a terminal apparatus of a superconducting device according to a second embodiment of the present invention;

FIG. 3 is a sectional view showing a terminal apparatus of a superconducting device according to a third embodiment of the present invention; and

FIG. 4 is a sectional view showing a terminal apparatus of a superconducting device according to a fourth embodiment of the present invention.

### DETAILED DESCRIPTION OF THE PREFERRED EMBODIMENT

Hereinafter, an explanation on a terminal apparatus of a superconducting device according to the preferred embodiments of the present invention will be in detail given with reference to the attached drawing. The explanation on the specific structure and functions are given just to define the preferred embodiments of the present invention, and the preferred embodiments of the present invention may be provided in various manners, which are not limited to the embodiments described below. In the description of the invention with reference to the attached drawings, further, the same components are indicated by the same reference numerals as each other, and for the brevity of the description, the explanation on their repeated features will be avoided.

According to the present invention, a terminal apparatus of a superconducting device does not need any dividing member for dividing a cryogenic temperature part in which a liquid refrigerant is contained and a temperature gradient part in which a vapor refrigerant is contained and also solves the problems caused when the liquid surface of the liquid refrigerant abnormally approaches a room temperature part.

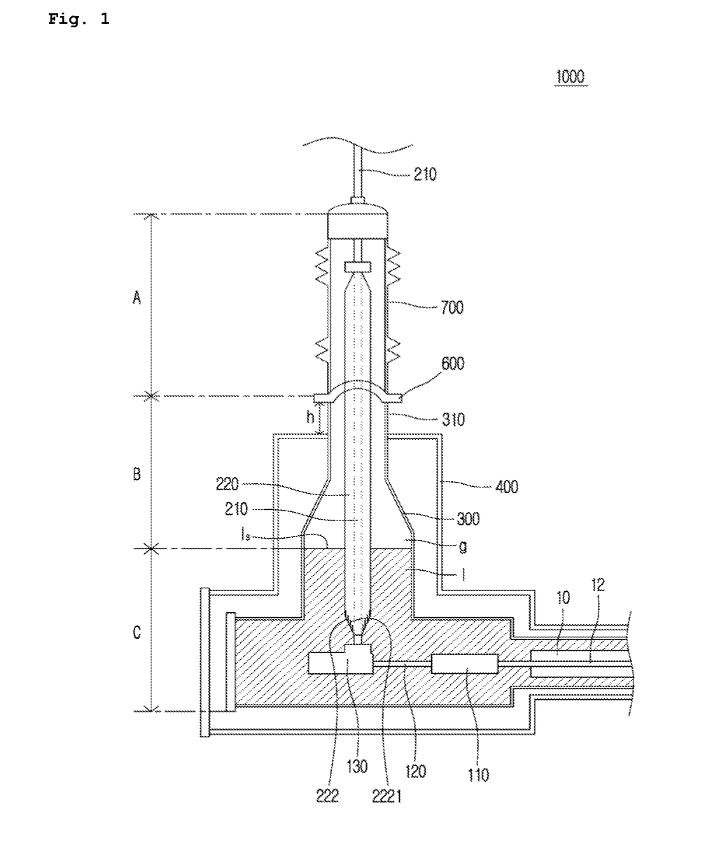

FIG. 1 is a sectional view showing a terminal apparatus of a superconducting device according to a first embodiment of the present invention.

A terminal apparatus 1000 of a superconducting device according to a first embodiment of the present invention includes: a cryogenic temperature part C containing a liquid refrigerant l in which a lower part of a conductor wire 210 is submerged therein, the conductor wire 210 being connected to a superconductor and having a bushing 220 fitted on the outer periphery thereof; a temperature gradient part B formed to communicate with the cryogenic temperature part C and to contain a vapor refrigerant g therein in such a manner as to have temperature gradient, in the state where the conductor wire 210 is extended upwardly from the cryogenic temperature part C; and a room temperature part A divided with the temperature gradient part B and having the conductor wire 210 extended from the cryogenic temperature part C and the temperature gradient part B and drawn to the outside, wherein the cryogenic temperature part C and a part of the temperature gradient part B are vacuum-insulated, and a part of the region beneath of the top end of the temperature gradient part B is exposed to the outside.

The terminal apparatus 1000 of a superconducting device is divided into the cryogenic temperature part C wherein the conductor wire 210 connected to the superconductor constituting the superconducting device is submerged into the cryogenic temperature liquid refrigerant l, the temperature gradient part B wherein the conductor wire 210 is located at the interior of the vapor refrigerant g contained to have a given temperature gradient as the height of the liquid surface ls of the liquid refrigerant contained in the cryogenic temperature part C is increased, and the room temperature part A divided with the temperature gradient part B and adapted to contain insulating oil or insulating gas therein at a room temperature environment, from which the conductor wire 210 is extended and drawn.

The cryogenic temperature part C in which the cryogenic temperature liquid refrigerant is contained and the temperature gradient part B in which the vapor refrigerant is contained are configured to communicate with each other, so that the liquid surface ls of the liquid refrigerant l contained in the cryogenic temperature part C can be increased in accordance with the temperature and internal pressure of the liquid refrigerant.

The cryogenic temperature part C and the temperature gradient part B are divided from each other in accordance with the liquid surface is of the liquid refrigerant contained in a refrigerant container 300.

The conductor wire 210 is connected to the superconductor 12. In this case, the connection of the conductor wire 210 to the superconductor 12 means both of the case where the conductor wire 210 is directly connected to the superconductor 12 by means of connection means like a connector, joint or other means and the case where the conductor wire 210 is indirectly connected to the superconductor 12 by adopting a connecting conductor 120 as will be described below.

That is, the end part of the superconductor 12 constituting the core of the superconducting device is connected to the connecting conductor 120 at a connection part 110, and the connecting conductor 120 connected through the connection part 110 to the superconductor 12 is electrically connected to the conductor wire 210 through the joint 130.

Even if not shown in FIG. 1, an insulating support material may be provided around the connection part 110 to remove the stress generated by thermal shrinkage.

The joint 130 provides a structure in which the connecting conductor 120 can be stably connected to the conductor wire 210, in spite of the horizontal shrinkage or tension of the connecting conductor 120 due to the temperature. For example, the joint 130 includes a flexible braided wire connecting member.

The conductor wire 210 connected to the joint 130 is extended toward the top end of the refrigerant container 300.

The conductor wire 210 is made of a copper (Cu) material or aluminum (Al) material and has the bushing 220 fitted around the outer periphery thereof. Of course, the conductor wire 210 may be formed of a bare conductor having no bushing 220 mounted thereon.

The copper and aluminum are examples of the conductive materials like metals having low electrical resistance at a refrigerant temperature used in the superconducting device, for example, even at a liquid nitrogen temperature when liquid nitrogen is used as the refrigerant.

The bushing 220 is formed by coating an insulating material like ethylene propylene rubber or fiber reinforced plastic (FRP) on the outer periphery of a stainless pipe.

Further, the bushing 220 has a plurality of foil electrodes 2221 formed vertically along the slant surfaces formed on the top end part and the bottom end part 222 in the lengthwise direction on the outer periphery thereof, and the part on which the foil electrodes 2221 are formed has a tapered shape.

The foil electrodes 2221 located on the bushing 220 may be adapted as electric field mitigation means.

The liquid refrigerant l contained into the cryogenic temperature part C and the vapor refrigerant g contained into the temperature gradient part B are stored in the refrigerant container 300 where refrigerants are generally contained. The refrigerant container 300 is made of metals like stainless having excellent strength.

The refrigerant container 300 is divided into a lower part wherein the cryogenic temperature part C in which the liquid refrigerant l is contained exists and an upper part wherein the temperature gradient part B exists in which the vapor refrigerant g is contained on top of the cryogenic temperature part C in such a manner as to have the temperature gradient thereof.

The refrigerant container 300 is configured wherein the liquid refrigerant l is contained in the lower part thereof, the vapor refrigerant g is in the upper part thereof, and the lower part of the conductor wire 210 is submerged into the liquid refrigerant l.

Further, the liquid surface is of the liquid refrigerant l contained in the lower part of the refrigerant container 300 is increased in accordance with the internal temperature or pressure of the liquid refrigerant. If the liquid refrigerant l is liquid nitrogen, the vapor refrigerant g is vapor nitrogen.

The terminal apparatus 1000 of the superconducting device according to the first embodiment of the present invention further includes a sealing member 600 for sealing the temperature gradient part B in such a manner as to be divided with the room temperature part A.

The top end of the refrigerant container 300 has open structure, and to seal the refrigerant container 300, the sealing member 600 is made of epoxy plastic having excellent cold resistance and corrosion resistance.

The room temperature part A is located above the temperature gradient part B and divided with the temperature gradient part B by the sealing member 600.

The conductor wire 210 is extendedly arranged at the inside of the room temperature part A, and the room temperature part A has a room temperature part housing 700 for surrounding the conductor wire 210 in such a manner as to contain the insulating oil or insulating gas (air or SF6 gas the like) therein. The room temperature part housing 700 may be composed of polymer material.

The conductor wire 210, which is passed through the room temperature part A, is drawn to the outside, while minimizing the impacts caused by the temperature changes.

The terminal apparatus 1000 of the superconducting device according to the first embodiment of the present invention does not have any separate flange member, partition or sealing material between the cryogenic temperature part C and the temperature gradient part B, thereby removing the problem that they are hardened or damaged through the exposure to the liquid refrigerant.

Accordingly, the height of the liquid surface ls on the upper part of the refrigerant container 300 in which the refrigerants of the cryogenic temperature part C and the temperature gradient part B are contained is generally increased in accordance with the temperature or pressure of the liquid refrigerant l. Of course, the drastic changes of the temperature or pressure of the vapor refrigerant in the temperature gradient part B give some influences on the height of the liquid surface ls.

The terminal apparatus 1000 of the superconducting device according to the first embodiment of the present invention does not have any member adapted to divide the cryogenic temperature part C and the temperature gradient part B from each other. If the liquid surface ls of the liquid refrigerant l is raised abnormally, it reaches the sealing member 600 dividing the room temperature part A and the temperature gradient part B and sealing the temperature gradient part B. If the liquid refrigerant l being at the cryogenic temperature state approaches the sealing member 600, the airtightness or durability of the sealing member 600 or the O-ring thereof may be damaged. So as to maintain the liquid surface is of the liquid refrigerant l contained in the refrigerant container 300 at a predetermined range, accordingly, a part of the refrigerant container 300 is exposed to allow heat intrusion or heat absorption under external environments to be artificially conducted on a partial region of the upper part of the temperature gradient part B of the refrigerant container 300.

The terminal apparatus 1000 according to the first embodiment of the present invention further includes a vacuum container 400 surrounding the refrigerant container 300 in such a manner as to allow a part of the region (indicated by a reference numeral 310) beneath the top end of the refrigerant container 300 containing the cryogenic temperature liquid refrigerant l and the vapor refrigerant g therein to be exposed to the outside.

In this case, the region 310 beneath the top end of the refrigerant container 300 means the region beneath the top end of the refrigerant container 300 where the sealing member 600 is provided, which is referred to as ‘the region 310 beneath the top end of the refrigerant container 300’.

The vacuum container 400 is configured to communicate with a vacuum insulation part of the superconducting device and to surround the lower part of the refrigerant container 300 as well as the refrigerant container 300.

In the first embodiment of the present invention as shown in FIG. 1, the vacuum container 400 is extended to the top part of the refrigerant container 300 to conduct the vacuum insulation of the refrigerant container 300.

As shown in FIG. 1, the vacuum container 400 does not surround the entire refrigerant container 300, but surrounds the refrigerant container 300 in such a manner as to allow the region 310 beneath the top end of the refrigerant container 300 to be somewhat exposed to the outside.

If the region 310 beneath the top end of the refrigerant container 300 is exposed to the outside, that is, to the room temperature environment, heat transfer or heat intrusion may be generated from a relatively higher temperature outside environment than the refrigerant being at the cryogenic temperature state.

Under the above-mentioned structure, a partial region of the upper part of the refrigerant container 300, that is, the upper end region thereof, which is not sealed by means of the vacuum container 400, is exposed to the room temperature environment.

If the region 310 beneath the top end of the upper part of the refrigerant container 300 is exposed to the room temperature, direct heat intrusion into the vacuum container 400 may be generated at the room temperature environment.

Through such artificial heat intrusion, the heat of the vapor refrigerant g inside the corresponding region is absorbed to cause the liquid surface ls to be decreased, thereby preventing the liquid surface ls of the liquid refrigerant l from approaching the sealing member 600 or the O-ring.

The refrigerant used for cooling the superconductor is nitrogen, and since the boiling point of nitrogen is −196° C., the vaporization of the liquid refrigerant l and the decrease of the liquid surface ls can be conducted through the heat absorption caused by just the exposure of the partial region of the upper part of the refrigerant container 300 to the room temperature environment.

That is, the heat transmitted to the refrigerant container 300 through the exposure of the partial region of the upper part of the refrigerant container 300 to the room temperature environment can be used for the vaporization process of the liquid refrigerant l around the liquid surface ls, thereby stopping or releasing the increase of the liquid surface ls. Of course, a part of the heat is used to heat the vapor refrigerant inside the temperature gradient part B.

The height h of the region 310 beneath the top end of the refrigerant container 300 exposed to the outside of the vacuum container 400 is proportional to the surface area of the region 310 beneath the top end of the refrigerant container 300, and the surface area exposed to the room temperature environment is proportional to the heating value transmitted to the refrigerant per unit time. Accordingly, the height h of the region 310 beneath the top end of the refrigerant container 300 is determined in consideration of the temperature of the external environment to permit the liquid surface ls of the liquid refrigerant l contained in the refrigerant container 300 to be located at a range between the lower end part of the bushing 222 surrounding the conductor wire 210 and the sealing member 600. Of course, in case where the liquid surface ls approaches the sealing member 600, the airtightness may be deteriorated, and therefore, the height h has a sufficient distance from the underside surface of the sealing member 600.

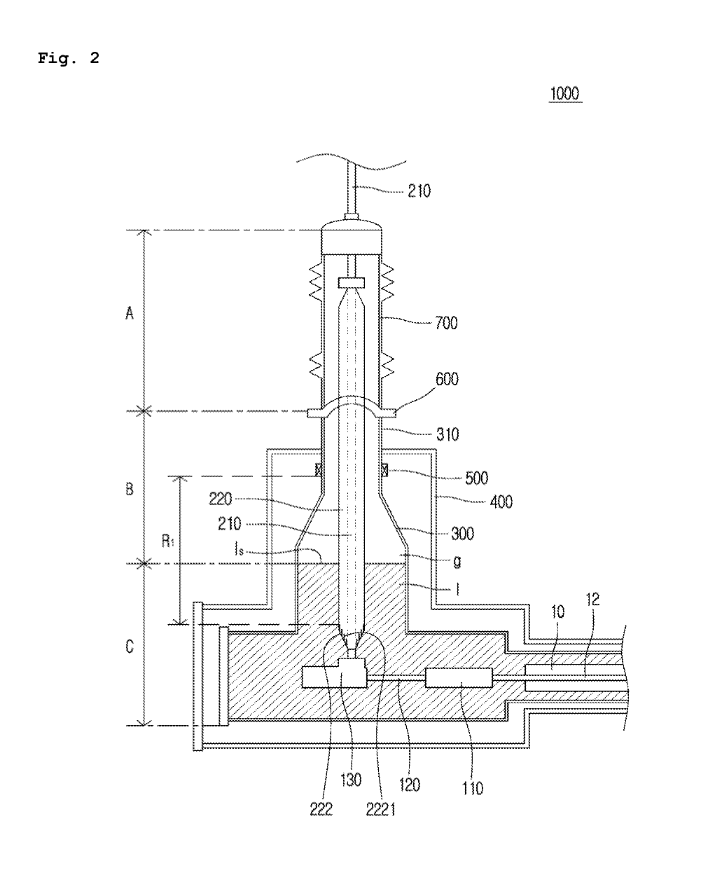

FIG. 2 is a sectional view showing a terminal apparatus of a superconducting device according to a second embodiment of the present invention, wherein the parts that have been already explained in FIG. 1 will be not explained again for the brevity of the description.

The terminal apparatus 1000 of the superconducting device according to the second embodiment of the present invention does not adopt any separate flange member, partition or sealing member dividing the cryogenic temperature part C and the temperature gradient part B, thereby removing the sealing member used for maintaining the airtightness therebetween. As shown in FIG. 1, further, the terminal apparatus 1000 of the superconducting device according to the second embodiment of the present invention has a structure where the vacuum insulation range of a vacuum container is adjusted to naturally prevent the liquid surface ls of the liquid refrigerant from being increased.

However, if the increase of the liquid surface ls is prevented just by the natural heat intrusion from the room temperature environment, the adjustment of the liquid surface ls of the liquid refrigerant is not carried out well when the external environment is drastically changed.

The terminal apparatus 1000 of the superconducting device as shown in FIG. 2 includes a liquid level controlling unit 500 adapted to prevent the liquid surface ls from being abnormally increased toward the sealing member 600 dividing the room temperature part A and the temperature gradient part B.

The liquid level controlling unit 500 may be a heater or cooler. According to the present invention, the heater as the liquid level controlling unit will be in detail described, and of course, the cooler is applicable to the present invention.

Accordingly, the terminal apparatus 1000 of the superconducting device according to the second embodiment of the present invention adopts a heater, especially, an electric heater as the liquid level controlling unit 500.

The liquid level controlling unit 500 is mounted on the outer peripheral surface of the refrigerant container 300, and it is formed of an electric heater adapted to heat the refrigerant container 300 in such a manner as to adjust the location of the liquid surface ls of the liquid refrigerant, thereby preventing the liquid surface ls of the liquid refrigerant in the refrigerant container 300 from approaching the sealing member 600. The electric heater is mounted on the outer peripheral surface of the refrigerant container 300, and it takes a shape of a band heater.

The liquid level controlling unit 500 is selectively operated to maintain the liquid surface ls of the liquid refrigerant l at a predetermined range R1.

In more detail, the electric heater as the liquid level controlling unit 500 is mounted on the outer peripheral surface of the refrigerant container 300, and the heat generated from the electric heater is conducted to the refrigerant container 300 generally made of a metal material to allow the liquid nitrogen on the liquid surface to be vaporized, thereby decreasing the height of the liquid surface ls.

In this case, so as to prevent the uppermost foil electrode 2221 of the plurality of foil electrodes 2221 provided on the lower end part 222 of the bushing 220 located on the outside of the conductor wire 210 from being exposed to the vapor refrigerant g due to the decrease of the liquid surface ls, the lower end of the predetermined range R1 is located over the height of the uppermost foil electrode 2221 mounted on the lower part of the bushing 220.

That is, the environment where the foil electrodes 2221 provided for the electric field mitigation are exposed is maintained constantly into the liquid refrigerant.

Further, the upper end of the predetermined range R1 becomes the lower end of the liquid level controlling unit 500.

That is, so as to prevent the liquid surface ls from being increased over the lower end height of the liquid level controlling unit 500 like the band heater, it is desirable to control the location of the liquid surface ls.

If the liquid level controlling unit 500 is located lower than the liquid surface ls, the heat generated from the electric heater 500 being operated is not used for the vaporization of the liquid refrigerant l on the liquid surface ls, but increases just the temperature of the liquid refrigerant beneath the liquid surface ls.

The terminal apparatus 1000 of the superconducting device according to the second embodiment of the present invention includes a controller (not shown) adapted to control the liquid level controlling unit 500, so that the liquid surface ls of the liquid refrigerant is maintained at the predetermined range R1. As mentioned above, the lower end of the predetermined range R2 is located over the height of the uppermost foil electrode 2221 mounted on the lower part 222 of the bushing 220 located on the outside of the conductor wire 210, and the upper end of the predetermined range R1 becomes the lower end of the liquid level controlling unit 500 mounted on the temperature gradient part B.

Further, the terminal apparatus 1000 of the superconducting device according to the second embodiment of the present invention includes at least one or more temperature sensing unit (not shown) or pressure sensing unit (not shown).

The temperature sensing unit includes a plurality of temperature sensors mounted spaced apart from each other on the temperature gradient part B and the cryogenic temperature part C, and the pressure sensing unit includes a plurality of pressure sensors mounted on the temperature gradient part B and the cryogenic temperature part C.

The temperature sensing unit or the pressure sensing unit is provided to sense the internal temperature or internal pressure of the refrigerants in the cryogenic temperature part C and the temperature gradient part B or to sense the internal temperature or internal pressure of the insulating material in the room temperature part A.

The location of the liquid surface ls of the liquid refrigerant is indirectly measured through the internal temperature or internal pressure of the refrigerants and the insulating material sensed by means of the temperature sensing unit or the pressure sensing unit, and based upon the measured location information of the liquid surface ls, the controller precisely controls the liquid level controlling unit 500.

The control variables of the liquid level controlling unit 500 through the controller are operating start point, operating time, and heating value per unit time of the liquid level controlling unit 500.

The heating value per unit time of the liquid level controlling unit 500 as the control variables of the controller is controlled by adjusting the size of the electric energy supplied to the heater constituting the liquid level controlling unit 500.

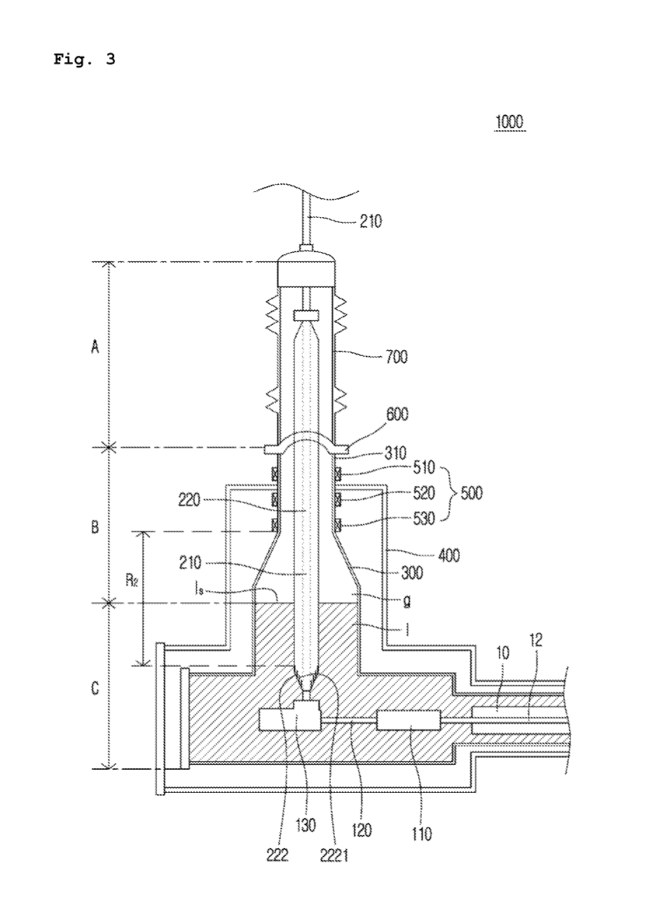

FIG. 3 is a sectional view showing a terminal apparatus of a superconducting device according to a third embodiment of the present invention, wherein the parts that have been already explained in FIGS. 1 and 2 will be not explained again for the brevity of the description.

The terminal apparatus 1000 of the superconducting device according to the third embodiment of the present invention is different from that according to the second embodiment of the present invention as shown in FIG. 2, in that a plurality of liquid level controlling units 510, 520 and 530 is adapted to artificially adjust the location of the liquid surface ls.

The terminal apparatus 1000 of the superconducting device as shown in FIG. 3 has the first to third liquid level controlling units 510, 520 and 530 mounted on the outer peripheral surface of the refrigerant container 300.

The first to third liquid level controlling units 510, 520 and 530 are mounted spaced apart from each other on the outer peripheral surface of the refrigerant container 300 along the arrangement direction of the conductor wire 210.

If the first to third liquid level controlling units 510, 520 and 530 are at the same time operated, a heating value per unit time is optimized to rapidly adjust the location of the liquid surface ls of the liquid refrigerant l.

Further, any one of the first to third liquid level controlling units 510, 520 and 530 is used as a main liquid level controlling unit, and the other two liquid level controlling units are used as auxiliary liquid level controlling units.

For example, the first liquid level controlling unit 510 among the first to third liquid level controlling units 510, 520 and 530 is operated always or alone as a main liquid level controlling unit, and the second and third liquid level controlling units 520 and 530 are operated as the auxiliary liquid level controlling units.

In the same manner as those in FIGS. 1 and 2, further, the third embodiment of the present invention as shown in FIG. 3 has a vacuum container 400 for surrounding at least a part of the refrigerant container 300.

The first liquid level controlling unit 510 is mounted on the outer peripheral surface of the refrigerant container 300 exposed to the room temperature environment, and the second and third liquid level controlling units 520 and 530 are mounted inside the vacuum container 400.

Accordingly, the first liquid level controlling unit 510 exposed to the room temperature environment is adapted to generate the heat lacking for the heat absorption from the room temperature environment and the decrease of the liquid surface.

Unlike the second and third liquid level controlling units 520 and 530 mounted inside the vacuum container 400, further, the first liquid level controlling unit 510 is exposed to the room temperature environment, thereby being advantageous in the maintenance or repairing. Accordingly, it is desirable that the liquid level controlling unit, which is not mounted inside the vacuum container, but exposed to the vacuum container, is used as the main liquid level controlling unit having long operating time or many operating times.

However, the method for exposing a part of the refrigerant container 300 where the refrigerant is contained to the room temperature environment is not applied necessarily together with the liquid level controlling units, but is applied selectively or together with the liquid level controlling units in accordance with the climate or weather changes of the area where the terminal apparatus 1000 of the superconducting device is installed.

For example, in the area where the seasons are not changed well, the surface of the refrigerant container 300 exposed to the room temperature environment is optimized to control the location of the liquid surface ls of the liquid refrigerant to reach the predetermined range, and contrarily, if the season change or the temperature change of the room temperature environment by daily temperature range is big, the electric heaters as the liquid level controlling units are auxiliarily adopted, thereby dynamically adjusting the location of the liquid surface ls of the liquid refrigerant.

The outer peripheral surface of the refrigerant container 300 on which the first liquid level controlling unit 510 is mounted is an external exposure range where heat intrusion from the room temperature environment is generated, and through the quantity of heat absorbed from the room temperature environment and the quantity of heat emitted from the first liquid level controlling unit 510, the location of the liquid surface ls of the liquid refrigerant can be most rapidly and effectively adjusted.

Accordingly, if the liquid surface ls of the liquid refrigerant l is raised abnormally, the second and third liquid level controlling units 520 and 530 are operated together with the first liquid level controlling unit 510, thereby rapidly adjusting the height of the liquid surface ls to the predetermined range.

Further, the controller controls the electric heaters as the liquid level controlling units to allow the electric heater exposed to the outside of the vacuum container 400 in such a manner as to be mounted on the outer peripheral surface of the refrigerant container 300 to have the operating time longer than that of the other electric heaters, to have the operating start point rapider than those of the other electric heaters, or to have the heating value per unit time larger than those of the other electric heaters.

If the first to third liquid level controlling units 510, 520 and 530 have the same output as each other, the heating values per unit time are determined upon the number of liquid level controlling units being operated among the plurality of liquid level controlling units. If the outputs of the respective electric heaters are adjustable, however, the heating values per unit time can be finely adjusted through the output adjustment of the respective electric heaters.

The controller controls the first to third liquid level controlling units 510, 520 and 530 independently of each other, and as mentioned above, controls them in such a manner as where at least one liquid level controlling unit has the operating start point, the operating time, and the heating value per unit time different from those of the other liquid level controlling units. Accordingly, the controller controls the first to third liquid level controlling units 510, 520 and 530, so that their operating start points, operating time, and heating values per unit time are different from each other.

Of course, the controller may control the first to third liquid level controlling units 510, 520 and 530, so that their operating start points, operating time, and heating values per unit time are same as each other.

In conclusion, the output, number or position of liquid level controlling units for adjusting the location of the liquid surface ls can be determined upon the room temperature environment where the terminal structure 1000 of the superconducting device is installed, and the area of the refrigerant container 300 exposed to the room temperature environment can be adjusted.

Further, in the third embodiment of the present invention as shown in FIG. 3, the first to third liquid level controlling units 510, 520 and 530 are selectively operated to maintain the liquid surface ls of the liquid refrigerant l at a predetermined range R2.

In this case, so as to prevent the uppermost foil electrode 2221 of the plurality of foil electrodes 2221 provided on the lower end part 222 of the bushing 220 located on the outside of the conductor wire 210 from being exposed to the vapor refrigerant g due to the decrease of the liquid surface ls, the lower end of the predetermined range R2 is located over the height of the uppermost foil electrode 2221, and the upper end of the predetermined range R2 becomes the lower end of the third electric heater 530 located at the lowermost end of the first to third liquid level controlling units 510, 520 and 530.

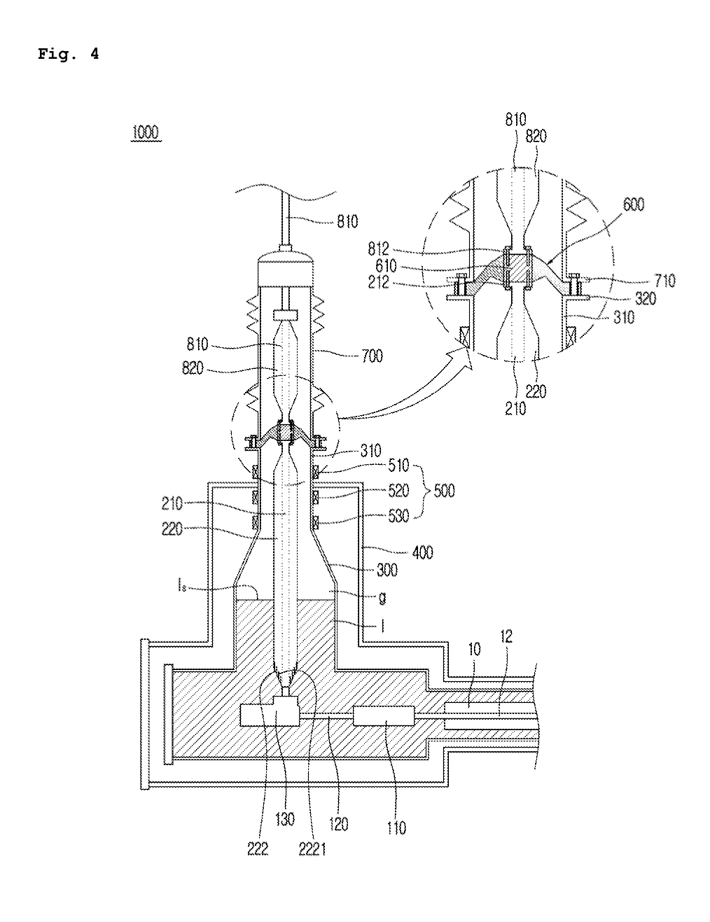

FIG. 4 is a sectional view showing a terminal apparatus of a superconducting device according to a fourth embodiment of the present invention, wherein the parts that have been already explained in FIGS. 1 to 3 will be not explained again for the brevity of the description.

Unlike the first to third embodiments of the present invention as shown in FIGS. 1 to 3, the fourth embodiment of the present invention as shown in FIG. 4 is configured wherein the room temperature part A is separable from the temperature gradient part B.

The terminal apparatus 1000 of the superconducting device as shown in FIG. 4 includes: a refrigerant container 300 where a liquid refrigerant is contained in the lower part thereof and a vapor refrigerant is contained on the top of the liquid surface of the liquid refrigerant; a first conductor wire 210 connected to a superconductor of the superconducting device in such a manner as to have the lower part submerged into the liquid refrigerant contained in the refrigerant container 300 and the upper part extended to the upper part of the refrigerant container 300 in which the vapor refrigerant is contained; a sealing member 600 for sealing the top end of the refrigerant container 300; a second conductor wire 810 detachably connected to the first conductor wire 210 by means of the sealing member 600 in such a manner as to be extended upwardly; a room temperature part housing 700 detachably mounted on the sealing member 600 to surround the second conductor wire 810 and containing insulating oil or insulating gas therein; and a vacuum container 400 adapted to allow the space where the liquid refrigerant is contained and a part of the space where the vapor refrigerant is contained in the refrigerant container 300 to be vacuum-insulated.

In the first to third embodiments of the present invention as shown in FIGS. 1 to 3, the conductor wire 210 connected to the superconductor of the superconducting device is passed through the sealing member 600 and extended to the room temperature part A.

That is, the terminal apparatus 1000 of the superconducting device, as shown in FIGS. 1 to 3, is divided into the room temperature part A, the temperature gradient part B and the cryogenic temperature part C by region and has one conductor wire 210, so that the room temperature part A and the temperature gradient part B are not easily separated from each other.

Accordingly, the terminal apparatus 1000 of the superconducting device, as shown in FIGS. 1 to 3, does not have any separation in the conductor wire 210, so that it may be complicated in the connection with an external device or connection box, large volume is needed, and an insulation weakness part is increased.

If the terminal apparatus 1000 of the superconducting device, as shown in FIGS. 1 to 3, is connected to an external device, it is complicated in terminal structure, occupies large volume, and increases its insulation weakness part.

So as to remove the above-mentioned problems, in the fourth embodiment of the present invention as shown in FIG. 4, the room temperature part A is detachably mounted on the temperature gradient part B.

That is, the room temperature part A is detachably mounted on the temperature gradient part B on the boundary of the sealing member 600.

The detachable mounting of the room temperature part A on the temperature gradient part B cannot be carried out by means of one conductor wire that is extended along the cryogenic temperature part C, the temperature gradient part B and the cryogenic temperature part C in such a manner as to be drawn to the room temperature environment, as shown in FIGS. 1 to 3.

Accordingly, in the fourth embodiment of the present invention as shown in FIG. 4, the first conductor wire 210 is disposed on the cryogenic temperature part C and the temperature gradient part B, that is, on the refrigerant container 300, and the second conductor wire 810 is located at the room temperature part housing 700 constituting the room temperature part A on the boundary of the sealing member 600. Further, a method is provided for connecting the first conductor wire 210 and the second conductor wire 810 at the sealing member 600.

That is, the two separated conductor wires 210 and 810 are provided on the terminal apparatus 1000 of the superconducting device, and the sealed refrigerant container 300 by means of the sealing member 600 and the room temperature part A can be separated from each other.

The sealing member 600 of the terminal apparatus 1000 of the superconducting device according to the fourth embodiment of the present invention includes a conductive connector 610 adapted to couple the first conductor wire 210 and the second conductor wire 810 to each other and to electrically connect them to each other.

The sealing member 600 is made of a material like epoxy, and the conductive connector 610 is made of a conductive metal material penetrating up and down into the sealing member 600.

The first conductor wire 210 and the second conductor wire 810 are fastened to the underside and top surfaces of the conductive connector 610 by means of fastening members like bolts.

Further, the top end periphery 320 of the refrigerant container 300 and the bottom end periphery 710 of the room temperature part housing 700 have flange structures so that the top end periphery 320 of the refrigerant container 300, the periphery of the sealing member 600, and the bottom end periphery 710 of the room temperature part housing 700 are fastened to each other by means of fastening members like bolts.

The second conductor wire 810, which is located inside the room temperature part A and fastened to the sealing member 600, has a bushing 820, and the room temperature part housing 700 contains insulating oil or insulating gas therein.

Accordingly, the second conductor wire 810 and the room temperature part housing 700 constituting the room temperature part A are separable from the sealing member 600, easily connected with another external device, and easy in the change of the intended usage of the terminal box, without having any separate connection box.

As described above, the terminal apparatus of the superconducting device according to the preferred embodiments of the present invention is configured to allow a part of the upper end region of the refrigerant container to be exposed to the room temperature environment, thereby somewhat releasing the problems caused by the increase of the liquid surface.

Further, the terminal apparatus of the superconducting device according to the preferred embodiments of the present invention adjusts the area of the refrigerant container exposed to the outside of the vacuum container in accordance with the environment on which the terminal apparatus is installed, thereby optimizing the height of the liquid surface of the liquid refrigerant in accordance with the room temperature environment.

Also, the terminal apparatus of the superconducting device according to the preferred embodiments of the present invention is capable of releasing the increase of the liquid surface, thereby improving the airtightness or durability of the sealing member or the O-ring.

Additionally, the terminal apparatus of the superconducting device according to the preferred embodiments of the present invention has the electric heaters as the liquid level controlling units, thereby artificially adjusting the location of the liquid surface of the liquid refrigerant.

Moreover, the terminal apparatus of the superconducting device according to the preferred embodiments of the present invention allows the room temperature part tube and the conductor wire located at the inside of the room temperature part tube, constituting the room temperature part, to be detachably mounted on the sealing member for sealing the refrigerant container, thereby enabling the room temperature part to be easily connected with another external device and to be easy in the change of the intended usage of the terminal box, without having any separate connection box.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A terminal apparatus of a superconducting device, comprising:
a refrigerant container having a cryogenic temperature part formed in the lower part thereof, the cryogenic temperature part containing a liquid refrigerant therein, and a temperature gradient part formed above the cryogenic temperature part, the temperature gradient part containing a vapor refrigerant having temperature gradient therein;
a sealing member for sealing the top end of the refrigerant container;
a room temperature part housing mounted on top of the sealing member in such a manner as to form a room temperature part in which insulating oil or insulating gas is contained;
a vacuum container for surrounding the refrigerant container except a part of the upper part thereof; and
a conductor wire connected to a superconductor of the superconducting device in the liquid refrigerant in the refrigerant container in such a manner as to be passed through the sealing member and extended to the room temperature part housing.

2. The terminal apparatus of a superconducting device according to claim 1, wherein the vacuum container surrounds the refrigerant container in such a manner as to allow the region beneath the top end of the refrigerant container to be exposed.

3. The terminal apparatus of a superconducting device according to claim 2, wherein the region beneath the top end of the refrigerant container exposed to the outside of the vacuum container has a height at which the liquid surface of the liquid refrigerant contained in the refrigerant container is located at a range between the lower end part of a bushing surrounding the conductor wire and the sealing member.

4. The terminal apparatus of a superconducting device according to claim 1, further comprising at least one or more liquid level controlling units mounted on the temperature gradient part or the cryogenic temperature part to vaporize the liquid refrigerant on the liquid surface in such a manner as to control the liquid surface of the liquid refrigerant to be located at a predetermined range.

5. The terminal apparatus of a superconducting device according to claim 4, wherein the liquid level controlling units comprise electric heaters mounted on the outer peripheral surface of the refrigerant container forming the temperature gradient part.

6. The terminal apparatus of a superconducting device according to claim 5, wherein the liquid level controlling units are mounted spaced apart from each other on the outer peripheral surface of the refrigerant container forming the temperature gradient part.

7. The terminal apparatus of a superconducting device according to claim 4, further comprising a controller for operating the liquid level controlling units in such a manner as to control the liquid surface of the liquid refrigerant contained in the refrigerant container to be located at the predetermined range.

8. The terminal apparatus of a superconducting device according to claim 7, wherein the lower end of the predetermined range is located at the height of the foil electrode disposed at the uppermost position among a plurality of foil electrodes mounted on the bushing located on the lower part of the conductor wire.

9. The terminal apparatus of a superconducting device according to claim 7, wherein the upper end of the predetermined range is located at the height of the lower end of the liquid level controlling unit mounted on the temperature gradient part.

10. The terminal apparatus of a superconducting device according to claim 9, wherein the liquid level controlling units are mounted spaced apart from each other on the outer peripheral surface of the refrigerant container forming the temperature gradient part, and the upper end of the predetermined range is located at the height of the lower end of the liquid level controlling unit disposed at the lowermost position among the liquid level controlling units mounted on the temperature gradient part.

11. A terminal apparatus of a superconducting device, comprising:
a refrigerant container containing a liquid refrigerant in the lower part thereof and a vapor refrigerant above the liquid refrigerant;
a first conductor wire connected to a superconductor of the superconducting device in such a manner as to have the lower part submerged into the liquid refrigerant contained in the refrigerant container and the upper part extended to the upper part of the refrigerant container in which the vapor refrigerant is contained;
a sealing member for sealing the top end of the refrigerant container;
a second conductor wire detachably connected to the first conductor wire by means of the sealing member in such a manner as to be extended upwardly;
a room temperature part housing detachably mounted on the sealing member to surround the second conductor wire and containing insulating oil or insulating gas therein; and
a vacuum container for surrounding the space where the liquid refrigerant is contained and a part of the space where the vapor refrigerant is contained in the refrigerant container to be vacuum-insulated.

12. The terminal apparatus of a superconducting device according to claim 11, wherein the sealing member comprises a conductive connector disposed at the center part thereof to couple the first conductor wire and the second conductor wire to each other.

13. The terminal apparatus of a superconducting device according to claim 11, further comprising at least one or more electric heaters mounted on the outer peripheral surface of the upper part of the refrigerant container in such a manner as to selectively generate heat therefrom to adjust the location of the liquid surface of the liquid refrigerant contained in the refrigerant container.

14. The terminal apparatus of a superconducting device according to claim 13, wherein the electric heaters are mounted spaced apart from each other on the outer peripheral surface of the refrigerant container, some of the electric heaters being mounted inside the vacuum container and the others being mounted on the outer peripheral surface of the refrigerant container exposed to the outside of the vacuum container.

15. The terminal apparatus of a superconducting device according to claim 14, further comprising a controller for operating the electric heaters to control the operating start point, operating time, and the heating value per unit time of at least one electric heater among the electric heaters to be different from those of the other electric heaters or to control the operating start points, operating time, and the heating values per unit time of the electric heaters to be same as each other.

16. The terminal apparatus of a superconducting device according to claim 15, wherein the controller operates the electric heater mounted on the outer peripheral surface of the refrigerant container exposed to the outside of the vacuum container to control the operating time thereof to be longer than that of the other electric heaters.

17. The terminal apparatus of a superconducting device according to claim 15, wherein the controller operates the electric heater mounted on the outer peripheral surface of the refrigerant container exposed to the outside of the vacuum container to control the operating start point thereof to be rapider than those of the other electric heaters.

18. The terminal apparatus of a superconducting device according to claim 15, wherein the controller operates the electric heater mounted on the outer peripheral surface of the refrigerant container exposed to the outside of the vacuum container to control the heating value per unit time thereof to be larger than those of the other electric heaters.

19. A terminal apparatus of a superconducting device, comprising:
a cryogenic temperature part containing a liquid refrigerant in which a lower part of a conductor wire is submerged therein, the conductor wire being connected to a superconductor and having a bushing fitted on the outer periphery thereof;
a temperature gradient part adapted to communicate with the cryogenic temperature part, containing a vapor refrigerant to have temperature gradient and having the conductor wire extended upwardly from the cryogenic temperature part; and
a room temperature part divided with the temperature gradient part, and having the conductor wire extended from the cryogenic temperature part and the temperature gradient part in such a manner as to be drawn therefrom;
wherein the cryogenic temperature part and a part of the temperature gradient part are vacuum-insulated, and a part of the region beneath the top end of the temperature gradient part is exposed to the outside.

20. The terminal apparatus of a superconducting device according to claim 19, further comprising at least one or more electric heaters mounted on the temperature gradient part or the cryogenic temperature part to vaporize the liquid refrigerant on the liquid surface in such a manner as to control the liquid surface of the liquid refrigerant to be located at a predetermined range.

21. The terminal apparatus of a superconducting device according to claim 20, wherein at least one electric heater of the electric heaters is mounted on the outer peripheral surface of the refrigerant container forming the temperature gradient part exposed to the outside.

22. The terminal apparatus of a superconducting device according to claim 19, wherein the room temperature part is detachably mounted on the temperature gradient part.

23. The terminal apparatus of a superconducting device according to claim 19, wherein the room temperature part and the temperature gradient part are divided from each other by means of the sealing member and have respective conductor wires detachably coupled to each other by means of the sealing member.
